(19) United States
(12) Patent Application Publication
(10) Pub. No.: US 2026/0302733 A1
(43) Pub. Date: Oct. 1, 2026

(54) LIGHT-EMITTING SEMICONDUCTOR ELEMENT AND METHOD OF MANUFACTURING SAME

(71) Applicant: NICHIA CORPORATION, Anan-shi, Tokushima (JP)

(72) Inventor: Yoji NAGAO, Tokushima-shi, Tokushima (JP)

(21) Appl. No.: 19/478,259

(22) PCT Filed: Apr. 24, 2024
(86) PCT No.: PCT/JP2024/016038

§ 371 Date: Oct. 23, 2025

(30) Foreign Application Priority Data
Apr. 27, 2023 (JP) 2023-073778

(51) Int. Cl. H01S 5/343

(52) U.S. Cl. CPC H01S 5/343

(57) ABSTRACT

A light-emitting semiconductor element includes a nitride semiconductor stack including a first semiconductor layer containing an n-type impurity, a compositionally graded layer containing the n-type impurity, a band gap energy in the compositionally graded layer decreasing as a distance from the first semiconductor layer increases; and a second semiconductor layer formed on the compositionally graded layer and containing the n-type impurity, a band gap energy in the second semiconductor layer being lower than a band gap energy of the first semiconductor layer. At least a portion of the compositionally graded layer and at least a portion of the second semiconductor layer contain the n-type impurity at a first concentration and a second concentration, respectively. At least one of the compositionally graded layer and the second semiconductor layer includes a high concentration region containing the n-type impurity at a third concentration that is higher than the first and second concentrations.

### CROSS-REFERENCE TO RELATED APPLICATIONS

This application is a U.S. National Phase application of International Application No. PCT/JP2024/016038 filed on Apr. 24, 2024, which claims priority to Japanese Patent Application No. 2023-073778, filed on Apr. 27, 2023. The entire disclosures of International Application No. PCT/JP2024/016038 and Japanese Patent Application No. 2023-073778 are hereby incorporated herein by reference.

### TECHNICAL FIELD

The present disclosure relates to a light-emitting semiconductor element and a method of manufacturing the same.

### BACKGROUND ART

Light-emitting semiconductor elements including nitride semiconductors that emit light in a range from ultraviolet to green are utilized in a broad range of applications such as light sources for optical discs. For such a light-emitting semiconductor element, a structure successively including on a substrate an n-side cladding layer, an n-side waveguide layer, an active layer, a p-side waveguide layer, and a p-side cladding layer is known (e.g., Japanese Patent Application Publication No. 2021-111785). Furthermore, the Al composition ratio is occasionally changed between the n-side cladding layer and the n-side waveguide layer for the purpose of controlling the conductivity or the like.

### SUMMARY

However, changing the Al composition ratio between the n-side cladding layer and the n-side waveguide layer might impede electron transport at the interface between the n-side cladding layer and the n-side waveguide layer to thereby increase the operating voltage.

A light-emitting semiconductor element according to the present disclosure comprises a nitride semiconductor stack having a first semiconductor layer containing an n-type impurity, a compositionally graded layer formed on the first semiconductor layer and containing the n-type impurity in which the band gap energy decreases as the distance from the first semiconductor layer increases, and a second semiconductor layer formed on the compositionally graded layer and containing the n-type impurity in which the band gap energy is lower than that of the first semiconductor layer. At least a portion of the compositionally graded layer contains the n-type impurity at a first concentration, at least a portion of the second semiconductor layer contains the n-type impurity at a second concentration, and at least one of the compositionally graded layer and the second semiconductor layer includes a high concentration region containing the n-type impurity at a third concentration that is higher than the first concentration and the second concentration.

A method of manufacturing a light-emitting semiconductor element according to the present disclosure comprises a process of forming a first semiconductor layer containing an n-type impurity, a process of forming a compositionally graded layer containing the n-type impurity in which the band gap energy decreases as the distance from the first semiconductor layer increases, and a process of forming a second semiconductor layer containing the n-type impurity and having a lower band gap energy than that of the first semiconductor layer in that order. In the process of forming a compositionally graded layer, at least a portion of the compositionally graded layer is doped with the n-type impurity at a first concentration. In the process of forming a second semiconductor layer, at least a portion of the second semiconductor layer is doped with the n-type impurity at a second concentration. In at least one of the processes of forming a compositionally graded layer and a second semiconductor layer, at least one of the compositionally graded layer and the second semiconductor layer is doped with the n-type impurity at a third concentration that is higher than the first concentration and the second concentration.

An embodiment of the present disclosure can provide a light-emitting semiconductor element in which the operating voltage can be effectively reduced, and method of manufacturing the same.

### BRIEF DESCRIPTION OF DRAWINGS

FIG. 1 is a schematic cross-sectional view showing a portion of a light-emitting semiconductor element structure according to an embodiment of the present invention.

FIG. 2A is a schematic cross-sectional view showing a portion of a nitride semiconductor stack structure in the light-emitting semiconductor element shown in FIG. 1.

FIG. 2B is a schematic cross-sectional view showing a portion of another semiconductor stack structure in the light-emitting semiconductor element shown in FIG. 1.

FIG. 3 is a schematic cross-sectional view of a light-emitting semiconductor element according to an embodiment.

FIG. 4 is a graph showing the current density-voltage (J-V) characteristics of the light-emitting semiconductor elements in an Example and a Comparative Example.

FIG. 5 is a graph showing the simulation results of the band diagram of the conduction band of the light-emitting semiconductor element in the Example.

FIG. 6 is a graph showing the simulation results of the band diagram of the conduction band in the light-emitting semiconductor element in the Comparative Example.

FIG. 7 is a schematic diagram showing the changes in the molar ratio of Al to the sum of Al and Ga, and the Si concentration in certain portions of the light-emitting semiconductor element according to an embodiment. The labels “Al” and “Si” represent the molar ratio of Al to the sum of Al and Ga, and the Si concentration, respectively.

### DESCRIPTION OF EMBODIMENT

Certain embodiments of the present invention will be described below with reference to the accompanying drawings. The embodiments below are examples provided to give shape to the technical ideas of the present invention, and are not intended to limit the present invention. The sizes of and positional relationships among the members shown in each drawing might be exaggerated for clarity of explanation. An end face view showing only a cut section might be used as a cross-sectional view. The same designations and reference numerals basically denote the same or similar members, for which redundant explanation will be omitted as appropriate.

In the present specification, in describing a light-emitting semiconductor element, the direction from the first semiconductor layer to the second semiconductor layer, or from the n-side semiconductor layer to the p-side semiconductor layer, will be called upwards or being above, and the opposite direction downwards or being below.

### Light-Emitting Semiconductor Element

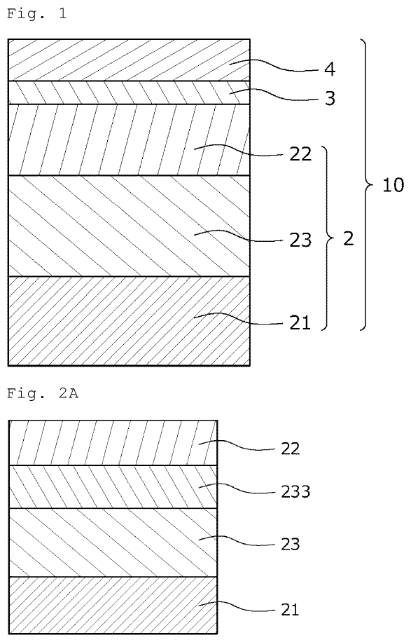

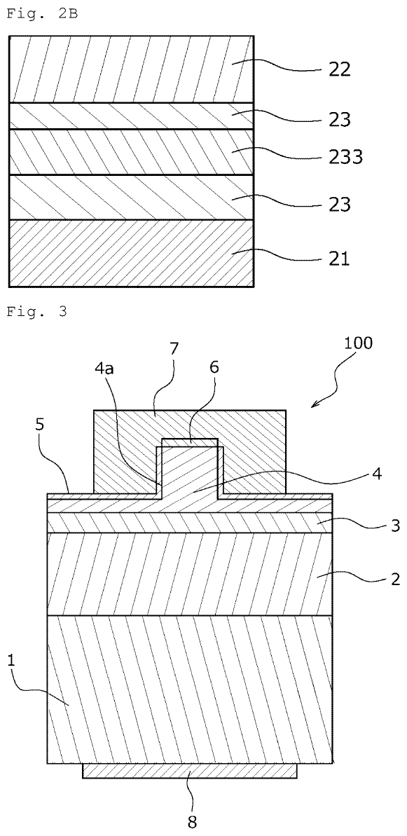

A light-emitting semiconductor element of the present disclosure, as shown in FIG. 1, includes a nitride semiconductor stack 10 that includes a first semiconductor layer 21 containing an n-type impurity, a compositionally graded layer 23, and a second semiconductor layer 22. The compositionally graded layer 23 contains an n-type impurity and is formed on the first semiconductor layer 21. the compositionally graded layer 23, the band gap energy decreases as the distance from the first semiconductor layer 21 increases. The second semiconductor layer 22 contains an n-type impurity and is formed on the compositionally graded layer 23. In the second semiconductor layer 22, the band gap energy is lower than the band gap energy of the first semiconductor layer 21.

At least a portion of the compositionally graded layer 23 contains the n-type impurity at a first concentration. At least a portion of the second semiconductor layer 22 contains the n-type impurity at a second concentration. At least one of the compositionally graded layer 23 and the second semiconductor layer 22 includes a high concentration region 233 containing the n-type impurity at a third concentration that is higher than the first concentration and the second concentration. In other words, the second semiconductor layer 22 alone may include a high concentration region 233, the compositionally graded layer 23 alone may include a high concentration region 233, or both the compositionally graded layer 23 and the second semiconductor layer 22 may each include a high concentration region 233.

If no compositionally graded layer 23 is provided between the first semiconductor layer 21 and the second semiconductor layer 22, a band barrier might occur at the hetero-interface between the first semiconductor layer 21 and the second semiconductor layer 22 to thereby increase the operating voltage. Providing a compositionally graded layer 23 between the first semiconductor layer 22 and the second semiconductor layer 22 can lessen the band barrier occurring at the hetero-interface and reduce the operating voltage. Furthermore, providing a region containing the n-type impurity at high concentration between the compositionally graded layer 23 and the second semiconductor layer 22 can reduce the operating voltage. Providing a region containing the n-type impurity at high concentration can relatively lower the n-type impurity concentration in the second semiconductor layer 22 to thereby reduce optical losses attributed to the n-type impurity.

### Nitride Semiconductor Stack 10

A nitride semiconductor stack 10, as shown in FIG. 1, further has an active layer 3 and a p-side semiconductor layer 4 in that order on the n-side semiconductor layer 2 which includes the first semiconductor layer 21, the compositionally graded layer 23, and the second semiconductor layer 22 described above.

The types of and the materials for the n-side semiconductor layer 2, the active layer 3, and the p-side semiconductor layer 4 are not particularly limited, and can include, for example, group III-V compound semiconductors, nitride semiconductors such as In_{X}Al_{Y}Ga_{1-X-Y}N (0≤X, 0≤Y, X+Y≤1), and the like. Specifically, InN, AlN, GaN, InGaN, AlGaN, InGaAlN, or the like can be used. Any thickness and stack structure known in the art can be utilized for each layer.

Furthermore, the light-emitting semiconductor element 100 that includes a nitride semiconductor stack 10 is preferably formed on a substrate as shown in FIG. 3. For the substrate 1, any substrate can be used as long as it allows for epitaxial growth of semiconductor layers. For such a substrate, for example, a nitride semiconductor substrate formed of GaN or the like, a sapphire substrate, or the like can be used. An example of the substrate 1 is one having C-plane (0001) as a principal face. The principal face of the substrate 1 may have an off-angle within ±5°. Employing a substrate having C-plane principal face can provide the benefit of achieving high production efficiency.

### N-Side Semiconductor Layer 2

An n-side Semiconductor layer 2 can be a multi-layer structure having a first semiconductor layer 21, a compositionally graded layer 23, and a second semiconductor layer 22 in that order. In the n-side semiconductor layer 2, for example, the first semiconductor layer 21 can serve as an n-side cladding layer, and the second semiconductor layer 22 can serve as an n-side optical waveguide layer.

The n-side semiconductor layer 2 contains an n-type impurity, such as Si, Ge, or the like. The n-type impurity concentration of the n-side semiconductor layer 2 can be suitably set in a range of 1×10¹⁶/cm⁻³ to 1×10²¹/cm⁻³, preferably 1×10¹⁷/cm⁻³ to 1×10²⁰/cm⁻³. Setting the n-type impurity concentration to 1×10¹⁷/cm⁻³ or higher allows the n-side semiconductor layer 2 to achieve good conductivity. Setting the n-type impurity concentration to 1×10²⁰/cm⁻³ at most can suppress optical losses attributed to an excessively high n-type impurity concentration. There may be a layer among those that constitute the n-side semiconductor layer 2 that does not contain an n-type impurity.

### First Semiconductor Layer 21

A first semiconductor layer 21 is, for example, an AlGAN layer, a GaN layer, an InGaN layer and/or an InGaAlN layer. Among all, the first semiconductor layer 21 is preferably an AlGaN layer. This can reduce the refractive index of the first semiconductor layer 21 to thereby increase the reflectance for the light from the compositionally graded layer 23 described later. In the case in which the first semiconductor layer 21 includes a semiconductor layer containing Al, the molar ratio of Al to the sum of Al and Ga is, for example, 0.005 to 0.2, preferably 0.01 to 0.1. Setting the molar ratio of Al to the sum of Al and Ga to 0.01 or higher can reduce the refractive index of the first semiconductor layer 21, thereby increasing the reflectance for the light from the compositionally graded layer 23 described later. Setting the molar ratio of Al to the sum of Al and Ga to 0.1 at most can reduce the occurrence of cracks during the crystal growth of the first semiconductor layer 21. The first semiconductor layer 21 contains an n-type impurity. For example, the first semiconductor layer can contain Si as an n-type impurity. The concentration of the n-type impurity in the first semiconductor layer 21 is referred to as the fourth concentration, which is, for example, 1×10¹⁸/cm⁻³ to 1×10¹⁹/cm⁻³, preferably 2×10¹⁸/cm⁻³ to 9×10¹⁸/cm⁻³. Setting the fourth concentration to 2×10¹⁸/cm⁻³ or higher allows the first semiconductor layer 21 to achieve good conductivity. Setting the concentration to 9×10¹⁸/cm⁻³ at most can reduce optical losses attributed to the n-type impurity.

The thickness of the first semiconductor layer 21 can be suitably set, for example, 1000 nm to 10000 nm.

### Compositionally Graded Layer 23

A compositionally graded layer 23 contains an n-type impurity and is disposed on the first semiconductor layer 21. The compositionally graded layer 23 is, for example, an AlGaN layer, a GaN layer, an InGaN layer and/or an InGaAlN layer. Among all, the compositionally graded layer 23 is preferably an AlGAN layer and/or a GaN layer when the first semiconductor layer 21 is an AlGaN layer and the second semiconductor layer 22 described later is a GaN layer. This can lessen the band barrier from the first semiconductor layer 21 to the second semiconductor layer 22, thereby reducing the operating voltage. The band gap energy in the compositionally graded layer 23 decreases as the distance from the first semiconductor layer 21 increases. In the case in which the compositionally graded layer 23 includes a semiconductor layer containing Al, the molar ratio of Al to the sum of Al and Ga is in a range, for example, of 0.005 to 0.2. The molar ratio of Al to the sum of Al and Ga decreases in this range as the distance from the first semiconductor layer 21 increases. In the case in which the compositionally graded layer is an AlGAN layer, for example, the Al composition ratio decreases as the distance from the first semiconductor layer 21 increases. For example, the molar ratio of Al to the sum of Al and Ga can be reduced from a first molar ratio in a range of 0.005 to 0.2 to a second molar ratio lower than the first molar ratio in a range of 0 to 0.18. Moreover, the molar ratio of Al to the sum of Al and Ga can be changed from a third molar ratio in a range of 0.06 to 0.1 to a fourth molar ratio in a range of 0 to 0.02, for example. In these cases, the molar ratio may be monotonically phased down or decreased linearly. Changing the molar ratio of Al to the sum of Al and Ga in the compositionally graded layer 23 in this manner can lessen the band barrier occurring at the hetero-interface to thereby reduce the operating voltage.

As long as the compositionally graded layer 23 contains an n-type impurity, the n-type impurity concentration may be the same across the entire compositionally graded layer 23 or different.

At least a portion of the compositionally graded layer 23 contains an n-type impurity at a predetermined concentration, and the concentration is referred to as a first concentration. The first concentration is, for example, in a range of 1×10¹⁸/cm⁻³ to 1×10¹⁹/cm⁻³, preferably 2×10¹⁸/cm⁻³ to 9×10¹⁸/cm⁻³. Setting the first concentration to 2×10¹⁸/cm⁻³ or higher allows the compositionally graded layer 23 to achieve good conductivity. Setting the concentration to 9×10¹⁸/cm⁻³ at most can reduce optical losses attributed to the n-type impurity.

The first concentration may be different from the fourth concentration and, for example, the first concentration is lower higher than the fourth concentration. The first concentration may be the same as the fourth concentration.

The region that contains an n-type impurity of a third concentration which is relatively higher than the first concentration and the second concentration described later will be referred to as the high concentration region 233. The third concentration may be, for example, in a range of 1×10¹⁸/cm⁻³ to 1×10²⁰/cm⁻³ after satisfying the condition of being higher than the first concentration and the second concentration. The third concentration may be in a range of 1×10¹⁹/cm⁻³ to 1×10²⁰/cm⁻³. Setting the third concentration to fall within this range can more effectively reduce the operating voltage. The third concentration may be 5×10¹⁸/cm⁻³ to 1×10²⁰/cm⁻³. Setting the concentration to fall within this range can more prominently achieve the operating voltage reduction effect. Particularly, the third concentration is preferably higher than the first concentration, the second concentration, and the fourth concentration. Setting the third concentration to a high value allows the Fermi level in the high concentration region 233 to shift towards the conduction band, thereby reducing the operating voltage.

Even when the concentrations other than the third concentration are low values, setting the third concentration at a high value can reduce the operating voltage. This allows the regions containing n-type impurities in concentrations other than the third concentration at low the n-type impurity concentrations to thereby reduce optical losses attributed to n-type impurities. The thickness of the high concentration region 233 is, for example, 0.1 nm to 10 nm, preferably 0.1 nm to 5 nm. Setting the thickness of the high concentration region 233 to 0.1 nm or larger can further reduce the operating voltage. Setting the thickness of the high concentration region 233 to 10 nm at most can reduce the region in which an n-type impurity is present at high concentration, thereby reducing optical losses attributed to the n-type impurity. Furthermore, setting the thickness of the high concentration region 233 to 5 nm at most can achieve a more enhanced optical loss reduction effect.

The composition gradient layer 23 may include a high concentration region 233. Allowing the compositionally graded layer 23 to include a high concentration region 233 can reduce the operating voltage. In the case in which the compositionally graded layer 23 contains an n-type impurity at the first concentration and includes a high concentration region 233, the high concentration region 233 is preferably in the shape of a layer. In other words, in a given plane of the compositionally graded layer 23, the n-type impurity concentration is either the first concentration or the third concentration at any location. The phrase, in a given plane, refers to a plane that is simultaneously grown in the semiconductor layer. In other words, a given plane is parallel to the interface between the first semiconductor layer 21 and the compositionally graded layer 23. The high concentration region 233 being a layer can have a high n-type impurity concentration at all locations in a given plane, thereby reducing the operating voltage at all locations in the plane.

In the case in which the compositionally graded layer 23 includes a high concentration region 233, the high concentration region 233 may be placed at the end part of the compositionally graded layer 23, or at least in one portion of the compositionally graded layer 23 excluding the end part. Being placed at least in one portion of the compositionally graded layer 23 excluding the end part refers to a state in which the compositionally graded layer 23 is present both above and under the high concentration region 233.

The thicknesses of the compositionally graded layer 23 and the high concentration region 233 can be suitably set according to the thicknesses of the n-side semiconductor layer 2, the active layer 3, and the p-side semiconductor layer 4. The thickness of the compositionally graded layer 23 is, for example, 5 nm to 50 nm, regardless of whether or not a high concentration region 233 is included. The thickness of the high concentration region 233 is smaller than the thickness of the compositionally graded layer 23. Such a configuration can achieve the band spike reduction effect while reducing optical losses attributed to the high concentration region 233.

In the case in which a high concentration region 233 is not included in the compositionally graded layer 23, a high concentration region 233 is included in the second semiconductor layer 22 described later. The second semiconductor layer 22 may include a high concentration region 233 when the compositionally graded layer 23 includes a high concentration region 233. In this case, the operating voltage reduction effect can be achieved by both the compositionally graded layer 23 and the second semiconductor layer 22. A high concentration region 233 does not have to be included in the second semiconductor layer 22 in the case in which the compositionally graded layer 23 includes a high concentration region 233. In this case, optical losses can be reduced in the second semiconductor layer 22.

The entire compositionally graded layer 23 except for the high concentration region 233 may have the same concentration. In the case in which the compositionally graded layer 23 does not include a high concentration region 233, the entire compositionally graded layer 23 may contain the n-type impurity at the first concentration. In the case in which the compositionally graded layer 23 includes a high concentration region 233, the entire compositionally graded layer 23 except for the high concentration region 233 may contain the n-type impurity at the first concentration. At least one portion of the compositionally graded layer 23 may contain the n-type impurity at a different concentration from the first concentration and the third concentration.

In the case in which the compositionally graded layer 23 includes a high concentration region 233, the n-type impurity concentration of the portion that is adjacent to the high concentration region 233 and located closer to the second semiconductor layer 22 than the high concentration region 233 is preferably is lower than the n-type impurity concentration of the portion that is adjacent to the high concentration region 233 and located closer to the first semiconductor layer 21 than the high concentration region 233 is. This can reduce the n-type impurity concentration in the portion that is closer to the second semiconductor layer 22 which has higher optical density than the first semiconductor layer 21, thereby reducing optical losses more effectively.

The high concentration region 233 is preferably not present between the first semiconductor layer 21 and the compositionally graded layer 23. This structure can reduce optical losses at the interface between the first semiconductor layer 21 and the compositionally graded layer 23.

The high concentration region 233 is preferably present in part, not across the entire compositionally graded layer 23. For example, the high concentration region 233 may be provided in a portion of the compositionally graded layer 23, or the high concentration region 233 does not have to be absent in the compositionally graded layer 23. This structure can further reduce optical losses resulting from providing a high concentration region 233.

### Second Semiconductor Layer 22

A second semiconductor layer 22 contains an n-type impurity and is formed on the compositionally graded layer 23. The second semiconductor layer 22 is, for example, an AlGaN layer, a GaN layer, an InGaN layer and/or an InGaAlN layer, preferably a GaN layer among all. This can lower the refractive index of the second semiconductor layer 22 to thereby efficiently retain light in the second semiconductor layer 22. The band gap energy of the second semiconductor layer 22 is lower than that of the first semiconductor layer 21. In the case in which the second semiconductor layer 22 includes a semiconductor layer containing Al, for example, the molar ratio of Al to the sum of Al and Ga is lower than the molar ratio of Al to the sum of Al and Ga in the first semiconductor layer 21. In the case in which the first semiconductor layer 21 is an AlGaN layer, for example, the molar ratio of Al to the sum of Al and Ga in the second semiconductor layer 22 is lower than that of the first semiconductor layer 21 or zero. Specifically, the molar ratio of Al to the sum of Al and Ga is in a range of 0 to 0.05.

The concentration of the n-type impurity in at least a portion of the second semiconductor layer 22 is referred to as a second concentration. The second concentration is preferably lower than the fourth concentration. The second concentration is preferably lower than the first concentration. Furthermore, the second concentration is preferably lower than the third concentration. Specifically, the second concentration is in a range of 1×10¹⁷/cm⁻³ to 1×10¹⁸/cm⁻³, preferably 2×10¹⁷/cm⁻³ to 9×10¹⁷/cm⁻³. Setting the second concentration to a low value can reduce optical losses attributed to the n-type impurity.

The second semiconductor layer 22 may include the high concentration region 233 described above. Allowing the second semiconductor layer 22 to include a high concentration region 233 can reduce the operating voltage. In the case in which the second semiconductor layer 22 contains an n-type impurity at the second concentration and includes a high concentration region 233, the high concentration region 233 is preferably in the form of a layer. In other words, in a given plane of the second semiconductor layer 22, the n-type impurity concentration at any location is either the second concentration or the third concentration. The phrase, in a given plane, refers to a plane that is simultaneously grown in the semiconductor layer. In other words, a given plane is parallel to the interface between the compositionally graded layer 23 and the second semiconductor layer 22. The high concentration region 233 being a layer can achieve high n-type impurity concentration at all locations of a given plane, thereby reducing the operating voltage at all locations in the plane.

In the case in which the second semiconductor layer 22 includes a high concentration region 233, the high concentration region 233 may be placed at the end part of the second semiconductor layer 22, or at least in one portion of the second semiconductor layer 22 excluding the end part. Being placed at least in one portion of the second semiconductor layer 22 excluding the end part refers to a state in which the second semiconductor layer 22 is present both above and under the high concentration region 233.

The thicknesses of the second semiconductor layer 22 and the high concentration region 233 can be suitably set in accordance with the thicknesses of the n-side semiconductor layer 2, the active layer 3, and the p-side semiconductor layer 4.

The thickness of the second semiconductor layer 22 is, for example, 5 nm to 50 nm, regardless of whether or not a high concentration region 233 is included.

In the case in which the second semiconductor layer 22 does not include a high concentration region 233, a high concentration region 233 is included in the compositionally graded layer 23.

The entire second semiconductor layer 22 except for the high concentration region 233 may have the same concentration. In the case in which the second semiconductor layer 22 does not include a high concentration region 233, the entire second semiconductor layer 22 may contain the n-type impurity at the second concentration. In the case in which the second semiconductor layer 22 includes a high concentration region 233, the entire second semiconductor layer 22 except for the high concentration region 233 may contain the n-type impurity at the second concentration. At least a portion of the compositionally graded layer 23 may contain the n-type impurity at a different concentration from the second concentration and the third concentration.

### Additional Layers

The n-side semiconductor layer 2 may further include an additional semiconductor layer as long as it successively has the first semiconductor layer 21, the compositionally graded layer 23, and the second semiconductor layer 22 as described above. An example is a stack structure successively having from the substrate side an underlayer, a crack suppressing layer, a first n-side cladding layer, a first n-side compositionally graded layer (i.e., the compositionally graded layer 23), an intermediate layer (i.e., the high concentration region 233), a first n-side optical waveguide layer (i.e., the second semiconductor layer 22), a second n-side compositionally graded layer, and a hole blocking layer. The hole blocking layer may include a first hole blocking layer and a second hole blocking layer. An n-type impurity may be added to the layers starting with the underlayer to the first n-side optical waveguide layer.

The underlayer may be, for example, an-type AlGAN layer. The crack suppressing layer may be, for example, an InGaN layer, which has larger band gap energy than that of the well layers of the active layer 3 described later. Providing a crack suppressing layer can reduce the probability of crack formation. For the first n-side cladding layer, a layer that is doped with an n-type impurity and has larger band gap energy than those of the underlayer and the crack suppressing layer, for example, can be employed. The first n-side cladding layer can be, for example, an AlGaN layer. The first n-side cladding layer may have the largest band gap energy in the n-side semiconductor layer 2. For the first n-side compositionally graded layer, for example, an AlGaN layer in which the Al composition ratio decreases as the distance from the first n-side cladding layer increases can be used. At the end of the first n-side compositionally graded layer on the intermediate layer side, the composition of the first n-side compositionally graded layer can be deemed as GaN. The intermediate layer has a lattice constant equivalent to that of the first n-side optical waveguide layer and can be, for example, a GaN layer. The intermediate layer is preferably smaller in thickness than the first n-side compositionally graded layer and the first n-side optical waveguide layer, for example.

The first n-side optical Waveguide layer is preferably a layer having a lower band gap energy and lower n-type impurity concentration than the first n-side cladding layer. The first n-side optical waveguide layer can be, for example, a GaN layer. The second n-side optical waveguide layer can be, for example, an undoped InGaN layer.

The second n-side compositionally graded layer may be a layer in which the band gap energy decreases as the distance to the active layer 3 decreases. In the case of forming a compositionally graded layer as the second n-side compositionally graded layer, the composition of the layer preferably changes such that the refractive index increases as the distance to the active layer 3 decreases. This can continuously form an optical waveguide barrier in the n-side compositionally graded layer, thereby enhancing the optical trapping in the active layer 3. In the case of providing in the n-side semiconductor layer 2 a compositionally graded layer in which the lattice constant increases as the distance to the active layer 3 decreases, the compositionally graded layer is preferably doped with an n-type impurity. A compositionally graded layer is, in other words, composed of multiple sublayers having slightly different compositions. For this reason, in a compositionally graded layer, the occurrence of fixed charges is difficult to avoid even with a small compositional change rate. When doped with an n-type impurity, fixed charges can be shielded. This can thus lessen the degree of voltage increase attributed to generation of fixed charges.

The hole blocking layer preferably contains an n-type impurity at least in part. This can more efficiently block holes. In the case in which the hole blocking layer is composed of a first hole blocking layer and a second hole blocking layer, the first hole blocking layer can be a GaN layer and the second hole blocking layer an InGaN layer, for example.

### Active Layer 3

An active layer 3 can be a multilayer structure composed of nitride semiconductor layers, such as GaN, InGaN, and the like. The active layer 3 has a single or multiple quantum well structure. A multiple quantum well structure can more easily provide optical gain than a single quantum well structure. In the case in which the active layer 3 is a multiple quantum well structure, the active layer 3 includes multiple well layers and intermediate barrier layers interposed by the well layers. For example, the active layer 3 includes, successively from the n-side semiconductor layer 2 side, a well layer, an intermediate barrier layer, and a well layer. An n-side barrier layer may be provided between the well layer closest to the n-side semiconductor layer 2 and the n-side semiconductor layer 2. The n-side barrier layer may be allowed to function as a part of the hole blocking layer. The n-side barrier layer may be omitted, and the hole blocking layer and the n-side optical waveguide layer may be allowed to function as n-side barrier layers. Similarly, a p-side barrier layer may be disposed between the well layer closest to the p-side semiconductor layer 4 and the p-side semiconductor layer 4. In the case in which no p-side barrier layer is provided or the p-side barrier layer is thin, a portion of the p-side semiconductor layer 4 may be allowed to function as the p-side barrier layer. In the case of including a p-side barrier layer in the active layer 3, the thickness of the p-side barrier layer can be, for example, 5 nm at most. As described above, moreover, doping with a p-type impurity increases light absorption losses. Thus, the active layer 3 is preferably formed without doping with a p-type impurity. Each layer in the active layer 3 can be an undoped layer, for example.

In the case in which the oscillation wavelength of the light-emitting semiconductor element is set to 530 nm or higher, the In composition ratio x of an InₓGa₁₋ₓN well layer may be slightly increased or decreased by the layer structure other than the active layer 3, for example, 0.25 or higher. The upper limit of the In composition ratio x of a well layer can be, for example, 0.50 at most.

### P-Side Semiconductor Layer 4

A p-side semiconductor layer 4 may include a protruded ridge 4a on the surface. The p-side semiconductor layer 4 can be a multilayer structure composed of nitride semiconductors, such as GaN, InGaN, AlGaN, and the like. The p-side semiconductor layer 4 can include a p-side cladding layer, a p-side optical waveguide layer, and other layers.

The p-side semiconductor layer 4 includes one or more p-type semiconductor layers. A p-type semiconductor layer is formed of, for example, a nitride semiconductor layer containing a p-type impurity such as Mg. The p-type semiconductor layers may include a layer containing the p-type impurity at a low concentration on the active layer 3 side such that the p-type impurity is undetectable by a SIMS analysis or the like. The low p-type impurity concentration layer can be set, for example, to 400 nm to 660 nm in thickness. The low p-type impurity concentration layer preferably includes a layer having a lower band gap energy than the layer containing a p-type impurity located above the low p-type impurity concentration layer.

The p-side semiconductor layer 4 may have, from the active layer 3 side, for example, an undoped p-side compositionally graded layer, an undoped p-side intermediate layer, a p-side electron barrier layer containing a p-type impurity and/or a p-type semiconductor layer containing a p-type impurity. The p-side compositionally graded layer can function as a p-side optical waveguide layer, for example. The thickness of the p-side compositionally graded layer is preferably in a range of 200 nm to 350 nm. In the case in which the p-side semiconductor layer 4 has a ridge 4a, the lower end of the ridge 4a is preferably not located in the p-side compositionally graded layer. The p-side electron barrier layer can be, for example, an AlGaN layer. In the case in which the p-side electron barrier layer is an AlGaN layer, the Al composition ratio can be set to 0.08 to 0.3. The thickness of the p-side electron barrier layer can be set, for example, to 5 nm to 100 nm.

The p-type semiconductor layer containing a p-type impurity can have a p-type impurity concentration of 1×10¹⁸/cm³ to 1×10²²/cm³, for example. The p-type semiconductor layer containing a p-type impurity can function as a p-side cladding layer and/or a p-side contact layer. The p-type semiconductor layer can be, for example, an AlGAN layer of GaN layer. The thickness of the p-side semiconductor layer 4 can be set to 5 nm to 300 nm, for example. The p-side semiconductor layer 4 does not have to include all of the layers described above, and has only to include any one or more of the layers.

For such a p-side semiconductor layer 4, for example, the semiconductor layers disclosed in Japanese Patent Application Publication No. 2020-115539 can be applied.

A light-emitting semiconductor element 100 including the nitride semiconductor stack 10 and the like described above includes a substrate 1, and an n-side semiconductor layer 2, an active layer 3, and a p-side semiconductor layer 4 disposed on the substrate as shown in FIG. 3. The light-emitting semiconductor element 100 can be, for example, an edge-emitting laser element having a light emission end face and a light reflecting end face that are orthogonal to the principal faces of the semiconductor layers such as the active layer 3. A ridge 4a is provided on the upper side of the p-side semiconductor layer 4. The ridge 4a has a mesa structure. The top view shape of the ridge 4a is an elongated shape that is long in the direction that connects the light emission end face and the light reflecting end face, for example, a rectangle having short sides in the direction parallel with the light reflecting end face and long sides in the direction perpendicular to the light reflecting end face. The portion of the active layer 3 directly under the ridge 4a and its vicinity constitute the optical waveguide region. An insulation film 5 can be provided on the lateral faces of the ridge 4a and the surface of the p-side semiconductor layer 4 continuous with the lateral faces of the ridge 4a. The substrate 1 is formed of an n-type semiconductor, for example, and an n-electrode 8 is provided on the lower face thereof. A p-electrode 6 is disposed in contact with the upper face of the ridge 4a, and a p-side pad electrode 7 is further disposed thereon.

Such a light-emitting semiconductor element 100 can have a structure to oscillate a laser light having a wavelength in a long wavelength range. A light-emitting semiconductor element 100 can oscillate a laser light in a wavelength range of blue or green light, for example, a laser light having a 420 nm or higher wavelength.

The insulation film 5 can be a single layer or multilayer film of an oxide or nitride of Si, Al, Zr, Ti, No, Ta, or the like, for example.

The n-electrode 8 is disposed over substantially the entire lower face of the n-type substrate 1.

The p-electrode 6 is disposed on the upper face of the ridge 4a. In the case in which the width of the p-electrode 6 is narrow, a p-side pad electrode 7 having a larger width than the p-electrode 6 can be provided on the p-electrode 6, and a wire or the like can be connected to the p-side pad electrode 7.

Examples of materials for each electrode include single layer or multilayer film of a conductive oxide or the like containing at least one selected from metals, such as Ni, Rh, Cr, Au, W, Pt, Ti, Al, or the like, or their alloys, Zn, In, and Sn. Examples of conductive oxides include ITO (indium tin oxide), IZO (indium zinc oxide), GZO (gallium-doped zinc oxide), and the like. The thickness of each electrode is, for example, 0.1 μm to 2 μm.

The p-electrode 6 is preferably a transparent conductive film having a lower refractive index than that of the active layer 3. This can allow the p-electrode to function as a cladding layer. For the p-electrode 6, for example, one formed of ITO can be used.

### Method of Manufacturing Light-Emitting Semiconductor Element

A method of manufacturing a light-emitting semiconductor element, for example, first forms a first semiconductor layer 21 containing an n-type impurity (S1). It then forms a compositionally graded layer 23 in which the band gap energy decreases as the distance from the first semiconductor layer 21 increases (S2). This is followed by forming a second semiconductor layer 22 having a lower band gap energy than the first semiconductor layer 21 (S3).

These first semiconductor layer 21, compositionally graded layer 23, and second semiconductor layer 22 are preferably formed on a substrate 1.

Semiconductor layers can be formed by any of the methods known in the art, such as MOCVD, sputtering, and the like. Semiconductor layers can be formed by using a MOCVD apparatus.

Semiconductor layers can be doped with an n-type impurity by introducing a gas containing an element for the n-type impurity when forming the semiconductor layers. At this time, the n-type impurity concentration can be adjusted by altering the concentration or the flow rate of the gas that contains the n-type impurity element. When forming the semiconductor layers, furthermore, the magnitudes of the band gap energy of the semiconductor layers can be adjusted by adjusting the compositions of the various types of gases that contain the raw materials for the semiconductors.

In one embodiment, for example, the compositionally graded layer 23 is compositionally graded by adjusting the concentration or the flow rate of at least one of the various types of gases containing semiconductor raw materials supplied during the formation of the semiconductor layer. Moreover, the compositionally graded layer 23 is formed to contain an n-type impurity at the first concentration by introducing a gas containing an element for the n-type impurity set at a predetermined concentration or flow rate.

Subsequently, a second semiconductor layer 22 is formed at a predetermined composition by supplying the various types of gases that contain semiconductor raw materials set at predetermined concentrations and flow rates. Furthermore, in the initial stage of forming the second semiconductor layer 22, a high concentration region 233 containing the n-type impurity at the third concentration is formed by supplying the gas containing the n-type impurity element set at a predetermined concentration or flow rate. Subsequently, the gas containing the n-type impurity element may be set at a predetermined concentration or the flow rate to allow the second semiconductor layer 22 to contain the n-type impurity at the second concentration. Following these processes allows the second semiconductor layer 22 to include a high concentration region 233 containing the n-type impurity at the third concentration which is higher than the first concentration and the second concentration.

In another embodiment, for example, the semiconductor layer is compositionally graded by adjusting the concentration or the flow rate of at least one type of the gases containing semiconductor raw materials supplied during the formation of the compositionally graded layer 23. At this time, a portion of the compositionally graded layer 23 is formed to contain an n-type impurity at the first concentration by introducing a gas containing an the n-type impurity element set to a predetermined concentration or flow rate. Then a high concentration region 233 containing the n-type impurity at the third concentration is formed as a part of the compositionally graded layer 23 by setting the gas containing an n-type impurity element to a predetermined concentration or flow rate. Then a portion at the compositionally graded layer 23 may be formed to contain the n-type impurity at the first concentration by supplying the gas containing the n-type impurity element set to a predetermined concentration or flow rate. Subsequently, the compositionally graded layer 23 may be completed in a stacked state such that the layers above and under the high concentration region 233 are the compositionally graded layers 23.

Subsequently, a second semiconductor layer 22 is formed to have a predetermined composition by supplying various types of gases that contain semiconductor raw materials set at predetermined concentrations and flow rates. At this time, supplying the gas containing the n-type impurity element set at a predetermined concentration or flow rate can form a second semiconductor layer 22 containing the n-type impurity at the second concentration on the compositionally graded layer 23 that is located above the high concentration region 233.

After forming the second semiconductor layer 22 in the process S3, by successively forming an active layer 3, a p-side semiconductor layer 4, an insulation film 5, a p-electrode 6, a p-side pad electrode 7, an n-electrode 8, and the like by using a known method, a light-emitting semiconductor element can be manufactured.

### Example 1

On an n-type GaN substrate (substrate 1) having (0001) plane as the upper face, a nitride semiconductor stack composed of an n-side semiconductor layer 2, an active layer 3 and a p-side semiconductor layer 4 was formed as described below.

First, the n-side semiconductor layer 2 was formed on the n-type GaN substrate (substrate 1) in a MOCVD apparatus, in the order of a 1.5 μm thick Al_{0.016}Ga_{0.984}N layer doped with Si to have a Si concentration that is 4×10¹⁸/cm⁻³ (underlayer), a 150 mm thick In_{0.04}Ga_{0.96}N layer doped with Si to have a Si concentration that is 1×10¹⁹/cm⁻³ (crack suppressing layer), a 900 mm thick Al_{0.08}Ga_{0.92}N layer doped with Si to have a Si concentration of 7×10¹⁸/cm⁻³ (first n-side cladding layer), a 19 nm thick first n-side compositionally graded layer doped with Si to have a Si concentration that is 7×10¹⁸/cm⁻³, a 1 nm thick GaN layer doped with Si at a Si concentration that is 7×10¹⁹/cm⁻³ (intermediate layer), a 350 nm thick GaN layer doped with Si to have a Si concentration that is 5×10¹⁷/cm⁻³ (first n-side optical waveguide layer), a 200 nm thick compositionally graded layer doped with Si to have a Si concentration that is 1×10¹⁸/cm⁻³ (second n-side compositionally graded layer), and a 1 nm thick GaN layer doped with Si to have a Si concentration that is 7×10¹⁹/cm⁻³ (hole blocking layer). The second n-side compositionally graded layer, set to begin with GaN and end with In_{0.05}Ga_{0.95}N, was formed by monotonically decreasing In in 120 phases so as to achieve a substantially linear compositionally graded.

Among the layers described above, the first n-side cladding layer that is the 7×10¹⁸/cm⁻³ Si concentration as the fourth concentration corresponds to the first semiconductor layer 21, the first n-side compositionally graded layer that is the 7×10¹⁸/cm⁻³ Si concentration as the first concentration corresponds to the compositionally graded layer 23, the intermediate layer that is the 7×10¹⁹/cm⁻³ Si concentration as the third concentration corresponds to the high concentration region 233, and the first n-side optical waveguide layer that is the 5×10¹⁷/cm⁻³ Si concentration as the second concentration corresponds to the second semiconductor layer 22.

Then an active layer 3 including an undoped In_{0.07}Ga_{0.83}N layer, an undoped In_{0.20}Ga_{0.80}N layer, and an undoped GaN layer in that order was grown.

Then for the p-side semiconductor 4, a 200 nm thick undoped compositionally graded layer, a 120 mm thick undoped GaN layer, a 130 nm thick undoped Al_{0.04}Ga_{0.96}N layer, a 10 mm thick Al_{0.25}Ga_{0.75}N layer doped with Mg to have a 2×10¹⁹/cm³ Mg concentration, a 100 mm thick Al_{0.04}Ga_{0.96}N layer doped with Mg to have a 8×10¹⁸/cm³ Mg concentration, and a 15 nm thick GaN layer doped with Mg to have a 1×10²⁰/cm³ Mg concentration were formed in that order. The p-side compositionally graded layer, set to begin with In_{0.05}Ga_{0.95}N and end with GaN, was formed by monotonically decreasing In in 120 phases so as to achieve a substantially linear compositionally graded.

Then the resultant nitride semiconductor stack was removed from the MOCVD apparatus, and a ridge 4a, an insulation film 5, a p-electrode 6, a p-side pad electrode 7, and an n-electrode 8 were formed. The ridge 4a was given a depth of about 280 nm. The p-electrode 6 was an ITO film of 200 nm in thickness. Subsequently, a reflecting film was formed on each of the light emission end face and the light reflecting end face, and the stack was cut into individual pieces to obtain semiconductor laser elements as light-emitting semiconductor elements 100. The peak wavelength of the laser light emitted by the resultant light-emitting semiconductor elements 100 was about 455 nm.

The Si concentration and the molar ratio of Al to the sum of Al and Ga change in the first semiconductor layer 21, the compositionally graded layer 23, the high concentration region 233, and the second semiconductor layer 22 among the layers described above as shown in FIG. 7. The molar ratio of Al to the sum of Al and Ga is constant in the first semiconductor layer 21, and decreases in the compositionally graded layer 23 as the distance from the first semiconductor layer 21 increases. Moreover, the molar ratio of Al to the sum of Al and Ga is constant in the high concentration region 233 and the second semiconductor layer 22.

The Si concentration is constant at the first concentration in the compositionally graded layer 23, and constant at the third concentration that is higher than the first concentration in the high concentration region 233. In the second semiconductor layer 22, the Si concentration is constant at the second concentration that is lower than the first concentration and the third concentration. The Si concentration in the first semiconductor layer 21 is constant at the fourth concentration that is the same as the first concentration.

The values in FIG. 7 merely show the magnitude relations qualitatively, and are not correct representation quantitatively. Furthermore, the changes in the Si concentration and the molar ratio of Al to the sum of Al and Ga in each layer are not limited to the examples shown in FIG. 7, and various modifications can be made as long as the purpose of the present disclosure can be achieved.

### Comparative Example 1

As Comparative Example 1, a light-emitting semiconductor element having a structure the same as or similar to that in Example 1 except for not including the compositionally graded layer 23 and the intermediate layer formed thereon in the n-side semiconductor layer 2 was produced. The peak wavelength of the light emitted by the light-emitting semiconductor element in Comparative Example 1 was about 455 nm.

### Experiment Results 1

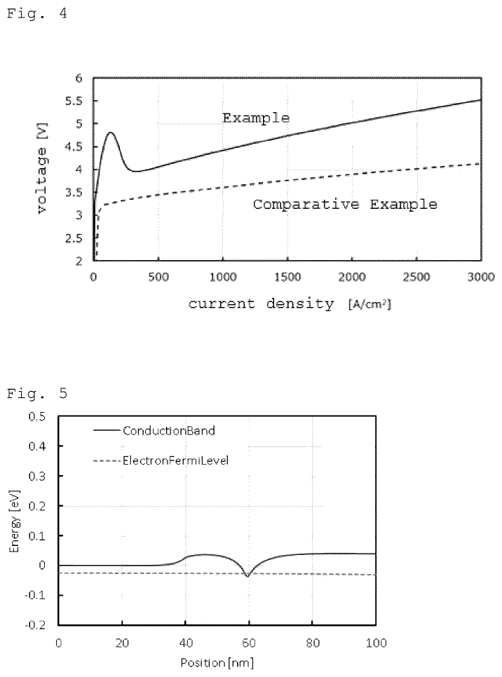

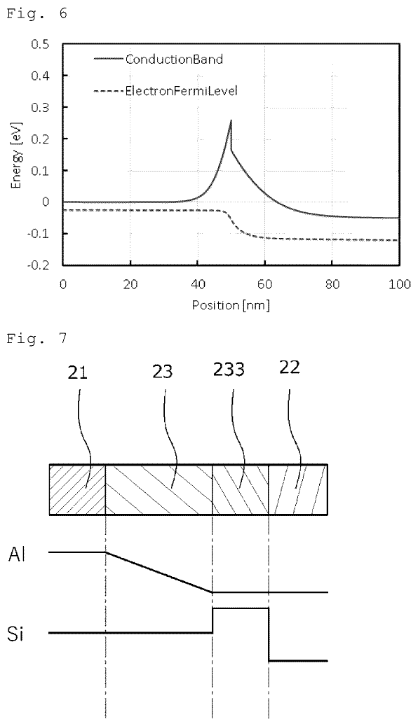

FIG. 4, FIG. 5, and FIG. 6 show the simulation results of the J-V characteristics and the band spikes of the light-emitting semiconductor elements of Example 1 and Comparative Example 1.

In Comparative Example 1, polarization charges accumulated at the hetero-interface to generate a band spike as shown by the simulation results in FIG. 6. This band spike becomes a barrier that impedes the electron flow to thereby increase the operating voltage as shown by the solid line in FIG. 4.

In contrast, the simulation results in FIG. 5 confirmed that the spike was lessened in the band in the light-emitting semiconductor element in Example 1. This, as a result, can reduce the operating voltage as shown by the broken line in FIG. 4.

The present application includes the aspects below.

(Aspect 1) A light-emitting semiconductor element comprising: a nitride semiconductor stack comprising: a first semiconductor layer containing an n-type impurity; a compositionally graded layer formed on the first semiconductor layer and containing the n-type impurity, the compositionally graded layer being in which a band gap energy decreases as a distance from the first semiconductor layer increases; and a second semiconductor layer formed on the compositionally graded layer and containing the n-type impurity, the second semiconductor layer being in which a band gap energy is lower than a band gap energy of the first semiconductor layer, wherein at least a portion of the compositionally graded layer contains the n-type impurity at a first concentration, at least a portion of the second semiconductor layer contains the n-type impurity at a second concentration, and at least one of the compositionally graded layer and the second semiconductor layer includes a high concentration region containing the n-type impurity at a third concentration that is higher than the first concentration and the second concentration.

(Aspect 2) The light-emitting semiconductor element according to (Aspect 1) wherein the first semiconductor layer contains the n-type impurity at a fourth concentration, and the second concentration is lower than the fourth concentration.

(Aspect 3) The light-emitting semiconductor element according to (Aspect 1) or (Aspect 2) wherein the second concentration is lower than the first concentration.

(Aspect 4) The light-emitting semiconductor element according to any one of (Aspect 1) to (Aspect 3), wherein
the first semiconductor layer contains the n-type impurity at a concentration in a range of 1×10¹⁸/cm⁻³ to 1×10¹⁹/cm⁻³,
the first concentration is in a range of 1×10¹⁸/cm⁻³ to 1×10¹⁹/cm⁻³, and
the second concentration is in a range of 1×10¹⁷/cm⁻³ to 1×10¹⁸/cm⁻³.

(Aspect 5) The light-emitting semiconductor element according to any one of (Aspect 1) to (Aspect 4) wherein a thickness of the compositionally graded layer is in a range of 5 nm to 50 nm.

(Aspect 6) The light-emitting semiconductor element according to any one of (Aspect 1) to (Aspect 5) wherein the third concentration is in a range of 1×10¹⁸/cm⁻³ to 1×10²⁰/cm⁻³.

(Aspect 7) The light-emitting semiconductor element according to any one of (Aspect 1) to (Aspect 6) wherein the high concentration region is a layer having a thickness in a range of 0.1 nm to 10 nm.

(Aspect 8) The light-emitting semiconductor element according to any one of (Aspect 1) to (Aspect 7) wherein the n-type impurity is Si.

(Aspect 9) A method of manufacturing a light-emitting semiconductor element comprising:
a process of forming a first semiconductor layer containing an n-type impurity;
a process of forming a compositionally graded layer containing the n-type impurity, the compositionally graded layer being in which a band gap energy decreases as a distance from the first semiconductor layer increases; and
a process of forming a second semiconductor layer containing the n-type impurity, the second semiconductor layer being in which a band gap energy is lower than a band gap energy of the first semiconductor layer,
the process of forming a first semiconductor layer, the process of forming a compositionally graded layer, and the process of forming a second semiconductor layer being performed in this order, wherein
in the process of forming a compositionally graded layer, at least a portion of the compositionally graded layer is doped with the n-type impurity at a first concentration,
in the process of forming a second semiconductor layer, at least a portion of the second semiconductor layer is doped with the n-type impurity at a second concentration,
in at least one of the process of forming the compositionally graded layer and the process of forming the second semiconductor layer, at least one of the compositionally graded layer and the second semiconductor layer is doped with the n-type impurity at a third concentration that is higher than the first concentration and the second concentration.

(Aspect 10) The method of manufacturing a light-emitting semiconductor element according to (Aspect 9) wherein
the process of forming the first semiconductor layer includes a process of doping at least a portion of the first semiconductor layer with the n-type impurity at a fourth concentration, and
the second concentration is lower than the fourth concentration.

(Aspect 11) The method of manufacturing a light-emitting semiconductor element according to (Aspect 9) or (Aspect 10) wherein the second concentration is lower than the first concentration.

(Aspect 12) The method of manufacturing a light-emitting semiconductor element according to any one of (Aspect 9) to (Aspect 11) wherein the second concentration is lower than the third concentration.

(Aspect 13) The method of manufacturing a light-emitting semiconductor element according to any one of (Aspect 9) to (Aspect 12) wherein the third concentration is in a range of 1×10¹⁸/cm⁻³ to 1×10²⁰/cm⁻³.

### REFERENCE NUMERALS

1: substrate; 2: n-side semiconductor layer; 21: first semiconductor layer; 22: second semiconductor layer; 23: compositionally graded layer; 233: high concentration region; 3: active layer; 4: p-side semiconductor layer; 4a: ridge; 5: insulation film; 6: p-electrode; 7: p-side pad electrode; 8: n-electrode; 10: semiconductor stack; and 100: light-emitting semiconductor element.

1. A light-emitting semiconductor element comprising
a nitride semiconductor stack including:
a first semiconductor layer containing an n-type impurity;
a compositionally graded layer formed on the first semiconductor layer and containing the n-type impurity, a band gap energy in the compositionally graded layer decreasing as a distance from the first semiconductor layer increases; and
a second semiconductor layer formed on the compositionally graded layer and containing the n-type impurity, a band gap energy in the second semiconductor layer being lower than a band gap energy of the first semiconductor layer, wherein
at least a portion of the compositionally graded layer contains the n-type impurity at a first concentration,
at least a portion of the second semiconductor layer contains the n-type impurity at a second concentration, and
at least one of the compositionally graded layer and the second semiconductor layer includes a high concentration region containing the n-type impurity at a third concentration that is higher than the first concentration and the second concentration.

2. The light-emitting semiconductor element according to claim 1, wherein
the first semiconductor layer contains the n-type impurity at a fourth concentration, and
the second concentration is lower than the fourth concentration.

3. The light-emitting semiconductor element according to claim 1, wherein the second concentration is lower than the first concentration.

4. The light-emitting semiconductor element according to claim 1, wherein
the first semiconductor layer contains the n-type impurity at a concentration in a range of 1×10¹⁸/cm⁻³ to 1×10¹⁹/cm⁻³,
the first concentration is in a range of 1×10¹⁸/cm⁻³ to 1×10¹⁹/cm⁻³, and
the second concentration is in a range of 1×10¹⁷/cm⁻³ to 1×10¹⁸/cm⁻³.

5. The light-emitting semiconductor element according to claim 1, wherein a thickness of the compositionally graded layer is in a range of 5 nm to 50 nm.

6. The light-emitting semiconductor element according to claim 1, wherein the third concentration is in a range of 1×10¹⁸/cm⁻³ to 1×10²⁰/cm⁻³.

7. The light-emitting semiconductor element according to claim 1, wherein the high concentration region is a layer having a thickness in a range of 0.1 nm to 10 nm.

8. The light-emitting semiconductor element according to claim 1, wherein the n-type impurity is Si.

9. A method of manufacturing a light-emitting semiconductor element comprising:
forming a first semiconductor layer containing an n-type impurity;
forming a compositionally graded layer containing the n-type impurity, a band gap energy in the compositionally graded layer decreasing as a distance from the first semiconductor layer increases; and
a process of forming a second semiconductor layer containing the n-type impurity, a band gap energy in the second semiconductor layer being lower than a band gap energy of the first semiconductor layer,
the forming of the first semiconductor layer, the forming of the compositionally graded layer, and the forming of the second semiconductor layer being performed in this order, wherein
the forming of the compositionally graded layer includes doping at least a portion of the compositionally graded layer with the n-type impurity at a first concentration,
the forming of the second semiconductor layer includes doping at least a portion of the second semiconductor layer with the n-type impurity at a second concentration,
at least one of the forming of the compositionally graded layer and the forming of the second semiconductor layer includes doping at least one of the compositionally graded layer and the second semiconductor layer with the n-type impurity at a third concentration that is higher than the first concentration and the second concentration.

10. The method of manufacturing a light-emitting semiconductor element according to claim 9, wherein
the forming of the first semiconductor layer includes doping at least a portion of the first semiconductor layer with the n-type impurity at a fourth concentration, and
the second concentration is lower than the fourth concentration.

11. The method of manufacturing a light-emitting semiconductor element according to claim 9, wherein the second concentration is lower than the first concentration.

12. The method of manufacturing a light-emitting semiconductor element according to claim 9, wherein the second concentration is lower than the third concentration.

13. The method of manufacturing a light-emitting semiconductor element according to claim 9, wherein the third concentration is in a range of 1×10¹⁸/cm⁻³ to 1×10²⁰/cm⁻³.
